(19) United States
(12) Patent Application Publication
(10) Pub. No.: US 2016/0311246 A1
(43) Pub. Date: Oct. 27, 2016

(54) Low Cost Screen Protector with Enhanced Appearance Vanishing Graphic Elements and Method of Manufacture

(71) Applicant: John Hill, Kissimmee, FL (US)

(72) Inventor: John Hill, Kissimmee, FL (US)

(21) Appl. No.: 14/697,533

(22) Filed: Apr. 27, 2015

(51) Int. Cl. B44C 1/24; C23C 14/34

(52) U.S. Cl. CPC B44C 1/24; C23C 14/34

(57) ABSTRACT

The present invention deals generally with a low cost method of making protective films for use on cell phones, smart phones, tablets, and computer or television display panels that incorporate graphical elements. Specifically, the protective films of the present invention are constructed with text and images embedded in the adhesive layer ordinarily associated with these films such that the embedded text and images appear under ambient light and vanish when the underlying screen is illuminated to display an image. The embedded images may be monochromatic or multichromatic.

### CROSS-REFERENCE TO RELATED APPLICATIONS

This application takes benefit of U.S. Provisional Appl. No. 61/994,846 filed May 17, 2014 which is incorporated in its entirety by reference.

### FIELD OF THE INVENTION

The present invention deals generally with a low cost method of making display protector films for use on cell phones, smart phones, tablets, and computer or television display panels that incorporate graphical elements. Specifically, the protective films of the present invention are constructed with text and images embedded in the adhesive layer ordinarily associated with these films such that the embedded text and images appear under ambient light and vanish when the underlying screen is illuminated to display an image. The embedded images may be monochromatic or multichromatic. Due to the application of metal particles on the adhesive layer of the film, designs created using this technique exhibit a diffuse, particularly rich appearance.

### BACKGROUND OF THE INVENTION

Numerous items today contain flat panel displays. Such flat panel displays include LCDs, LEDs, and plasma displays. Unlike old fashioned cathode-ray displays which featured a stout, scratch resistant glass front panel, most flat panel displays are constructed of plastic or very thin glass, or some combination of both. The former scratches easily and the latter can be broken if not carefully handled. As a result, various kinds of screen protectors have been created. Usually constructed of thin transparent plastic material, these screen protectors are pre-cut to fit various devices and adhere to the display electrostatically or by means of a low-tack adhesive. These screen protectors come in a wide variety of shapes and appearances. Most are largely or completely transparent. Others have printing on that part of the screen protector that is to be placed over the “dead area” of the device—i.e. the areas of the device that surround the display. Others are available featuring a mirrored surface. These screen protectors are made using a layer of very thinly deposited reflective metallic particles. As a result, when the display is not illuminated the screen protector appears to be a mirrored surface. When the display is on, however, sufficient light passes through the screen protector so that the image generated by the display can be seen by the user. Such mirrored films may be created in any shade of gray or in a variety of colors ranging from red to silver to gold to pink to blue to violet.

### BRIEF DESCRIPTION OF THE INVENTION

The present invention concerns itself with protective films that are provided with a low-tack adhesive applied on one side. The present invention utilizes at least one type of reflective metal particle applied in a pattern to create a graphical element comprising images, graphics, text, and/or logos embedded within the adhesive layer such that when applied to the display of the device and the device is off and/or unilluminated the graphical element is visible under ambient light but when the screen is on and illuminated the graphical element largely disappears. In this embodiment, the invention is comprised of a transparent polyester base film with silicone or acrylic low-tack adhesive on one side. The graphical element is comprised of at least one thin layer of reflective metallic particles sputtered or otherwise applied to at least part of the surface area of the adhesive layer. The area(s) of the screen protector subjected to the sputtering process and comprising the graphical element each necessarily obscure less than 100% of the total surface area of the screen protector covering the illuminated display of the device. The graphical element is preferably comprised of at least two kinds of metallic particles or the same kind of metallic particles applied in different densities. Due to the application of metal particles on the adhesive layer of the film, designs created using this technique exhibit a particularly rich appearance.

When the graphical element is comprised of two different metallic particles, different colors may be obtained. For example, the image of a gold star superimposed on a silver filled circle may be created. When a protective film featuring these graphical elements is applied to a display panel, the image would appear as a gold star superimposed on a silver filled circle when the display is not illuminated and would largely vanish when the display is illuminated. Similarly, when different densities of the same metallic particles are used, multiple shades of a single color may be used to create the graphical element. For example, an image may be created in which a star is rendered in a relatively thick layer of silver reflective particles and a surrounding circle is rendered in a relatively thin layer of silver reflective particles. When a protective film featuring these graphical elements is applied to a display panel, the image would appear as an obvious silver star superimposed on a pewter filled circle when the display is unilluminated and would largely vanish when the display is illuminated.

### BRIEF DESCRIPTION OF THE DRAWINGS

FIG. 1 is a top view of a multi-toned display screen protective film with monochrome reflective graphical elements.

FIG. 2 is a top view of a display screen protective film with multi-colored reflective graphical elements.

### DETAILED DESCRIPTION OF THE INVENTION

Traditional mirrored film is made by coating a transparent substrate polymer film such as, without limitation, polyester terephthalate (PET), polyester napathalate (PEN), Kapton®, Ultem®, cellulose tri-acetate (TAC), and cyclo-olefin polymer (COP) with a thin coating of reflective substances. Such substances include various metals and their metal alloys and metal oxides, including, without limitation: aluminum, copper, gold, indium, nichrome, palladium, platinum, silicon, silver, stainless steel, tin, tungsten, vanadium, and zirconium. Various ceramic materials may be used also. Ordinarily the polymer film is coated by means of conventional vacuum or sputter deposition in which the polymer film substrate is exposed to an ionized vapor of the selected metal and the metal particles physically bond to the surface of the polymer film substrate. By mixing more than one material or adding trace amounts of various gasses during the sputtering process, a wide range of colors may be achieved. For example, Al₂O₃ sputtered in combination with trace amounts of V₂O₃ provides a blue film. Al₂O₃ sputtered with a trace amount of NiO provides a yellow film. TiN is one of the oldest sputtered coatings, providing the familiar gold color of modern architectural windows. Blue (TiAl)N thin film coatings are created by sputtering Ti and Al with varying amounts of N. The concentration of N in the sputter chamber controls the vibrancy of the resulting blue color.

As the length of time the film is exposed to the ionized vapor is increased, the thickness and density, and thus the reflectivity and opacity, of the metalized polymer film also increases. At the limit, 100% coverage of the surface area of the film is achieved and the surface is brilliantly reflective yet completely opaque. For example, such a metallized polymer film featuring aluminum, gold, silver, etc. applied by means of magnetron sputtering is described in U.S. Pat. No. 5,631,066. In many cases however, brilliant reflectivity coupled with complete opacity is less than desirable. For example, a reflective window film that is completely opaque is usually undesirable. As a result, by limiting the amount of time the polymer film is exposed to the metal vapor, a relatively thin coating may be achieved that visually has a mirrored surface, but has a thickness and density low enough that a substantial portion of the light that impinges on the polymer film passes through unobstructed.

Numerous methods are well known in the art whereby such metal plated polymer films may be further processed to create intricate patterns. U.S. Pat. No. 4,440,801 describes numerous techniques available to do this. For example, a metal coated polymer film may be coated with a resist layer which is later exposed to light defining the pattern of the metal to be left on the polymer film. After the unwanted metal is removed, only the desired pattern remains. Before the remaining resist layer is removed, such a polymer film may be re-subjected to an additional conventional vacuum or sputter deposition operation this time with a different metal and treated with a second resist layer defining an additional part of the pattern. After the unwanted second metal and the exposed resist layers are removed only the desired two color design remains. This process can be repeated any number of times to create multicolored mirrored images on film.

However, the methods discussed above are directed towards sputtering metal on a clean film. However, for use as a screen protector the sputtered film must be overcoated with another film to protect the sputtered layer from oxidation and to secure the sputtered material in place. This is important for films that are expected to have a long service life. For use as a screen protector, adhesive is then usually applied to one of the films. Such multi-laminar examples are relatively expensive to manufacture.

It is possible to sputter on a clean film and apply adhesive to the side of the film that was sputtered, but this precludes using low-cost, readily available clear films with adhesive already applied. Such films are widely available with various kinds of low tack adhesives pre-applied, the most prominent of which are acrylic or silicone adhesives with ultra-low to very low adhesion characteristics (e.g. from about 0.5 to about 10.0 grams per inch). Given the ubiquity and low-cost of such films, it would be desirable to possess a one-step method of sputtering directly on the film but in such a way that an additional film layer is not required to protect the sputtered surface. What is needed then is a method of sputtering directly on the adhesive layer of these low cost, readily available plastic films. This would speed the manufacturing process and decreases costs associated with creating the sputtered films, and thus screen protectors, made using the technique. Since screen protectors are not expected to have a long service life, such a screen protector made using one embodiment of the present invention installed with the combined adhesive/sputtered layer between the film and the screen provides sufficient protection from oxidation and fingerprints for normal use.

Another disadvantage of existing techniques in the prior art is that they create mirrored films that are just that—mirrored—with a flat, reflective appearance. The films created using one embodiment of the present invention differ in that they are far less reflective, i.e. they exhibit a richer, more matted appearance. The principle reason for this is that the sputtered metal is deposited on the adhesive layer and the adhesive layer is, itself, unevenly applied at a microscopic level. As a result, the film reflects light back in a variety of directions, not just one like a conventional mirror. Thus, while the films created by one embodiment of the present invention are generally not suitable for use as a mirror per se, they are aesthetically superior when creating graphical elements. While the method of the present invention may be practiced using a variety of sputtering targets and sputtering thicknesses, the metals, metal oxides, and metal alloys disclosed in the present application function best when sputtered for a time sufficient to deposit a layer in the range of about 10 nm to about 140 nm and preferably in the range of about 40 nm to about 80 nm.

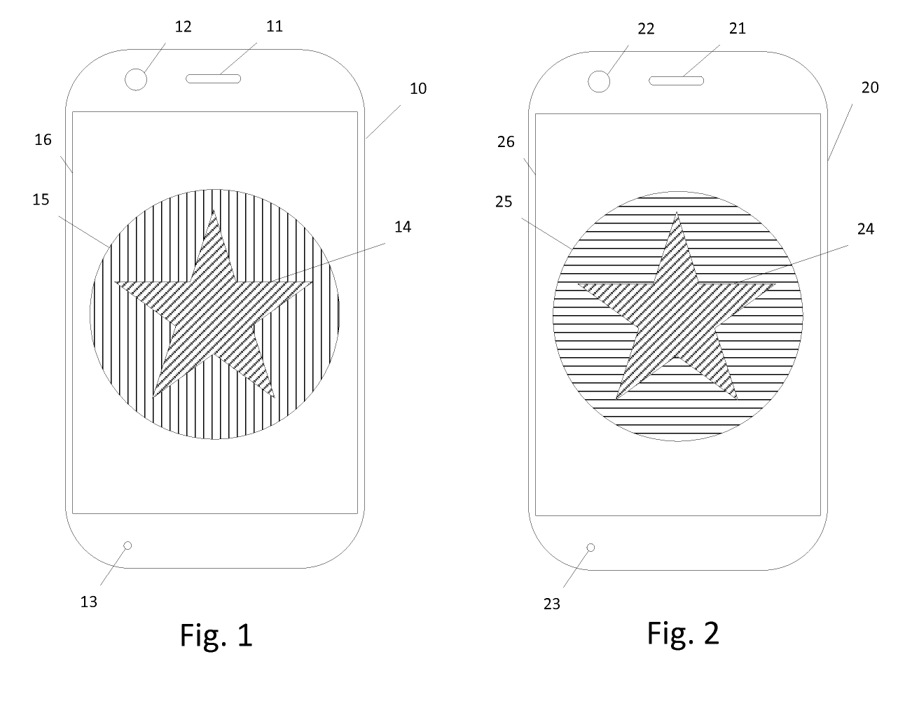

Turning now to FIG. 1, an example of this method is provided whereby a polymer film with pre-applied low-tack adhesive layer may be treated to create a silver star 14 on a darker silver filled circle 15 and subsequently die cut to form screen protector 10 wherein the method comprises the steps of: 1) Removing the protective layer supplied with the film covering the adhesive (if supplied in this form); 2) Placing the film in a sputtering chamber with the newly exposed adhesive layer facing the sputtering source; 3) Subjecting it first to a conventional vacuum or sputter deposition operation with an intervening open star-shaped mask to create a centrally located 60 nm Al layer in the form of star 14; 4) Re-subjecting it to a shorter second conventional vacuum or sputter deposition operation with an intervening open circular mask with blocked star area to create a centrally located 40 nm Al layer in the form of circle 15 cut-out to closely follow the outline of star 14; 5) Die-cutting the piece to the proper size and shape to form screen protector 10 and forming various perforations including an earpiece aperture 11, a camera aperture 12, and a microphone aperture 13; and, 6) Covering the newly sputtered adhesive side with a temporary protective covering that will be removed when screen protector 10 is applied to the device. In this example, star 14 will be silver while circle 15 upon which it is superimposed will be a pewter color when display 16 is unilluminated. When display 16 is illuminated the design largely disappears from view. Of course, it will be readily apparent that these operations are preferably performed in a dust-free or dust-limited environment to preclude contamination of the adhesive layer as it is sputtered.

Turning now to FIG. 2, an example of this method is provided whereby a polymer film with pre-applied low-tack adhesive layer may be treated to create a silver star 24 on a gold circle 25 and subsequently die cut to form screen protector 20. Since gold is slightly more reflective than aluminum, a slightly thinner layer of gold has roughly the same reflectivity and VLT as a thicker layer of aluminum. The following steps comprise the method in this case: 1) Removing the protective layer supplied with the film covering the adhesive (if supplied in this form); 2) Placing the film in a sputtering chamber with the newly exposed adhesive layer facing the sputtering source; 3) Subjecting it first to a conventional vacuum or sputter deposition operation with an intervening open star-shaped mask to create a centrally located 60 nm Al layer in the form of star 24; 4) Re-subjecting it to a shorter second conventional vacuum or sputter deposition operation with an intervening open circular mask with blocked star area to create a centrally located 50 nm Au layer in the form of circle 25 cut-out to closely follow the outline of the star 24; 5) Die-cutting the piece to the proper size and shape to form screen protector 20 and forming various perforations including an earpiece aperture 21, a camera aperture 22, and a microphone aperture 23; and, 6) Covering the newly sputtered adhesive side with a protective covering that will be removed when screen protector 20 is applied to the device. In this example, star 24 will be silver while the filled circle 25 upon which it is superimposed will be equally intense gold when display 26 is unilluminated. When display 26 is illuminated the design largely disappears from view. As above, it will be readily apparent that these operations are preferably performed in a dust-free or dust-limited environment to preclude contamination of the adhesive layer as it is sputtered.

It will be readily apparent to those having skill in the art that more than two separate sputtering operations may be sequentially done rendering complex images in different colors by varying the material sputtered and the gaseous environment in which the sputtering operation takes place, and in various intensities by varying time sputtered (and thus the thickness of the sputter layer). Similarly, the steps of sputtering and die-cutting need not be performed in the order disclosed; indeed the steps may be performed completely independent of one another. Finally, those having skill in the art will recognize not only the metals, metal alloys, and metal oxides disclosed may be sputtered, but other types of materials may be included or substituted. For example, various ceramic sputtering targets may be used for one or more sputtering operations. It will be equally apparent that metal and ceramic sputtering may be combined on a single piece to achieve unique visual effects.

It will be readily apparent to those having skill in the art that a wide variety of polymer films are amenable to the teachings of the present invention, including, but not limited to: polyethylene, polyvinyl chloride, polycarbonate, polystyrene, polyamide, polyethylene terephthalate (PET), polytetrafluoroethylene, cellulose, cellophane, and so on. Alternative transparent film materials, such as carbon fiber nanotube film, may be used as a substrate also. Moreover, those having skill in that art will recognize that the substrate need not be film or film-like, and may be any solid, plate, or block material, including, but not limited to, glass, sapphire, and spinel.

What is claimed is:

1. A transparent polymer layer with a pre-applied adhesive coating on one side treated to display a pattern wherein:
a. at least one area on said pre-applied adhesive layer is subjected to a first vapor deposition operation to create a graphical element.

2. A transparent polymer layer with a pre-applied adhesive coating on one side treated to display a pattern of claim 1 wherein:
a. at least one additional area on said adhesive layer is subjected to a second vapor deposition operation to create at least one additional graphical element.

3. A transparent polymer layer with a pre-applied adhesive coating on one side treated to display a pattern of claim 2 wherein said first and second vapor deposition operations use the same sputter deposition target material and sputter exposure times.

4. A transparent polymer layer with a pre-applied adhesive coating on one side treated to display a pattern of claim 2 wherein said first and second vapor deposition operations use the same sputter deposition target material but different sputter exposure times.

5. A transparent layer with a pre-applied adhesive coating on one side treated to display a pattern of claim 2 wherein said first and second vapor deposition operations use different sputter deposition target materials.

6. A transparent polymer layer with a pre-applied adhesive coating on one side treated to display a pattern of claim 2 wherein said first and second vapor deposition operations deposit material in a thickness ranging from about 10 nm to about 140 nm.

7. A transparent polymer layer with a pre-applied adhesive coating on one side treated to display a pattern of claim 2 wherein said first and second vapor deposition operations deposit material in a thickness ranging from about 40 nm to about 80 nm.

8. A transparent polymer layer with a pre-applied adhesive coating on one side treated to display a pattern of claim 1, wherein the area of said part of said adhesive layer subjected to said first vapor deposition operation displaying said graphical element is less than 100% of the total surface area of said transparent polymer layer with some portion of the area of said part of said adhesive layer being un-subjected to said vapor deposition coating.

9. A transparent polymer layer with a pre-applied adhesive coating on one side that is treated to display a pattern of claim 1, wherein said transparent polymer layer is cut into a plurality of screen protectors each of which further comprises a plurality of through holes corresponding to the location of a camera lens, speaker aperture, and microphone aperture, if any.

10. A method of making a transparent polymer layer with a pre-applied adhesive coating on one side treated to display a pattern comprising the steps of:
a. removing the protective layer supplied with the film covering the adhesive, if any;
b. placing the film in a sputtering chamber with the newly exposed adhesive layer facing the sputtering source;
c. subjecting the adhesive layer to a sputter deposition operation; and
d. recovering the newly sputtered surface with protective film.

11. A method of making a screen protector with multiple graphical elements with an adhesive layer on one side comprising the steps of:
a. removing the protective layer covering the adhesive layer of the film, if any;
b. placing the film in a sputtering chamber with the newly exposed adhesive layer facing a first sputtering source;
c. insinuating a first mask between said first sputtering source and the film such that a graphical element in the shape of the opening formed in the mask will be formed on the adhesive layer of the film after sputtering on the film;
d. subjecting the film to a first sputtering operation;
e. insinuating an open mask between said first sputtering source and the film such that a graphical element in the shape of the opening formed in the mask will be formed on the adhesive layer of the film after sputtering on the film;
f. subjecting the film to a second sputtering operation;
g. recovering the newly sputtered surface with protective film; and
h. cutting the film to form a screen protector in the proper size while simultaneously forming any needed apertures.

12. A method of making a screen protector with multiple graphical elements with an adhesive layer on one side of claim 11 wherein said first and second vapor deposition operations deposit material in a thickness ranging from about 10 nm to about 140 nm.

13. A method of making a screen protector with multiple graphical elements with an adhesive layer on one side of claim 11 wherein said first and second vapor deposition operations deposit material in a thickness ranging from about 40 nm to about 80 nm.

14. A method of making a screen protector with multiple graphical elements with an adhesive layer on one side of claim 11 wherein said first and second vapor deposition operations use the same sputter deposition target material and sputter exposure time.

15. A method of making a screen protector with multiple graphical elements with an adhesive layer on one side of claim 11 wherein said first and second vapor deposition operations use the same sputter deposition target material but different sputter exposure times.

16. A method of making a screen protector with multiple graphical elements with an adhesive layer on one side of claim 11 wherein said first and second vapor deposition operations use different sputter deposition target materials.
